(19) United States
(12) Patent Application Publication
(10) Pub. No.: US 2026/0333635 A1
(43) Pub. Date: Oct. 22, 2026

(54) LIQUID COOLING DEVICE

(71) Applicant: SHENZHEN APALTEK CO., LTD., Shenzhen (CN)

(72) Inventors: Dagao ZHENG, Shenzhen (CN); Minrui CHEN, Shenzhen (CN); Xuelong WANG, Shenzhen (CN)

(21) Appl. No.: 19/438,497

(22) Filed: Dec. 31, 2025

(30) Foreign Application Priority Data
Apr. 17, 2025 (CN) 2025104889821

(51) Int. Cl. H05K 7/20

(52) U.S. Cl. CPC H05K 7/20336

(57) ABSTRACT

A liquid cooling device includes a water cooling head assembly, a heat dissipation module, and a water cooling radiator assembly. The water cooling head assembly includes a water cooling plate attached to a heat source and a water cooling shell combined with the water cooling plate. An embedding groove is formed on the water cooling plate and located on the side facing the water cooling shell. Pipe joints are provided on the water cooling shell. The heat dissipation module includes multiple heat dissipation fins and at least one heat pipe. One end of the heat pipe passes through the heat dissipation fins, and the other end is combined in the embedding groove. The water cooling radiator assembly includes a water cooling radiator and multiple connecting pipes. One end of the connecting pipe is connected to the water cooling radiator, and the other end is connected to the pipe joint.

### BACKGROUND OF THE DISCLOSURE

### Technical Field

The present disclosure relates to a cooling device, and particularly relates to a liquid cooling device.

### Description of Related Art

Related-art air cooling methods usually have difficulties to dissipate large amounts of heat to the external environment within a short period of time, so they have gradually become inadequate. Consequently, water cooling has been widely used in high-performance electronic devices. Furthermore, water cooling devices are operated by placing a water cooling head in direct contact with the heat source for heat exchange, so as to transfer the heat through a coolant to a heat sink for dissipation.

However, after a period of operation, the temperature of the shell of the water cooling head also increases, leading to a reduction in heat transfer efficiency. Therefore, the research motivation of the present disclosure is to reduce the temperature of the shell of the water cooling head in order to effectively transfer the heat generated by electronic devices and improve the heat dissipation efficiency.

In view of the deficiencies of the related art, the present disclosure conducted researches based on the existing technologies and the application of theories, and finally developed a liquid cooling device in accordance with the present disclosure to overcome the deficiencies of the related art.

### SUMMARY OF THE DISCLOSURE

The primary objective of the present disclosure is to provide a liquid cooling device to reduce the temperature of a water cooling plate, so as to improve the heat dissipation efficiency of the liquid cooling device.

To achieve the aforementioned objective, the present disclosure provides a liquid cooling device, used for dissipating heat from a heat source, which includes a water cooling head assembly, a heat dissipation module and a water cooling radiator assembly. The water cooling head assembly includes a water cooling plate attached to a heat source and combined with a water cooling shell of the water cooling plate, the water cooling plate is provided with at least one embedding groove located at a corresponding location on an outer periphery of the water cooling shell and on a side facing the water cooling shell, and the water cooling shell has a plurality of pipe joints. The heat dissipation module includes a plurality of heat dissipation fins and at least one heat pipe, wherein one end of the heat pipe is passed with the heat dissipation fins, and another end of the heat pipe is combined in the embedding groove. The water cooling radiator assembly includes a water cooling radiator and a plurality of connecting pipes, wherein one end of the connecting pipe is connected to the water cooling radiator, and another end of the connecting pipe is connected to the pipe joints respectively.

In an embodiment of the present disclosure, the water cooling head assembly includes a plurality of water cooling fins arranged with a space apart from each other on the water cooling plate, and the water cooling fin protrudes inside the water cooling shell.

In an embodiment of the present disclosure, the water cooling plate is formed with a recess at the center position thereof, and the water cooling fin is located in the recess.

In an embodiment of the present disclosure, the periphery of the water cooling plate is formed with a protruding platform, and the embedding groove is located on the protruding platform.

In an embodiment of the present disclosure, the water cooling plate and the water cooling shell after being stacked are combined together, and then secured by a plurality of screws.

In an embodiment of the present disclosure, the heat dissipation module further includes a cooling fan combined with a side of the heat dissipation fin.

In an embodiment of the present disclosure, there are multiple embedding grooves and multiple heat pipes, and the embedding grooves are located on different sides of the periphery of the water cooling plate.

In an embodiment of the present disclosure, the heat dissipation module further includes a fan frame of the cooling fan, the fan frame has a plurality of protruding plates facing the water cooling head assembly, the heat dissipation fin is provided with a plurality of locking plates, and the fan frame is passed and secured to the protruding plate and the locking plate through a plurality of fasteners to combine the cooling fan with a side of the heat dissipation fin.

In an embodiment of the present disclosure, there are multiple heat dissipation modules located on opposites sides of the water cooling head assembly respectively.

In an embodiment of the present disclosure, the liquid cooling device further includes a water pump installed in the water cooling shell

Compared to the related art, the water cooling head assembly of the liquid cooling device of the present disclosure includes a water cooling plate and a water cooling shell combined with the water cooling plate, and the water cooling plate is provided with an embedding groove disposed at a corresponding location of the outer periphery of water cooling shell and on a side facing the water cooling shell. In addition, the heat dissipation module of the liquid cooling device of the present disclosure includes a plurality of heat dissipation fins and at least one heat pipe, and one end of the heat pipe is passed with the heat dissipation fin, and another end of the heat pipe is combined in the embedding groove of the water cooling plate. In this way, the heat pipe absorbs heat from the water cooling plate and conducts the heat to the heat dissipation module to quickly remove and dissipate the heat, thereby cooling the water cooling plate and achieving continuous heat dissipation for the heat generating components.

### BRIEF DESCRIPTION OF THE DRAWINGS

FIG. 1 is a perspective view of a liquid cooling device of the present disclosure;

FIG. 2 is a perspective assembled view of a water cooling head assembly of the present disclosure;

FIG. 3 is a plan configuration view of a heat dissipation module of the present disclosure;

FIG. 4 is a perspective assembled view of a heat dissipation module of the present disclosure; and

FIG. 5 is a cross-sectional assembled view of a water cooling head assembly of the present disclosure.

### DETAILED DESCRIPTION

The detailed description and technical contents of the present disclosure are illustrated with reference to the accompanying drawings, which are intended for the illustrative purposes only, but not intended for limiting the disclosure.

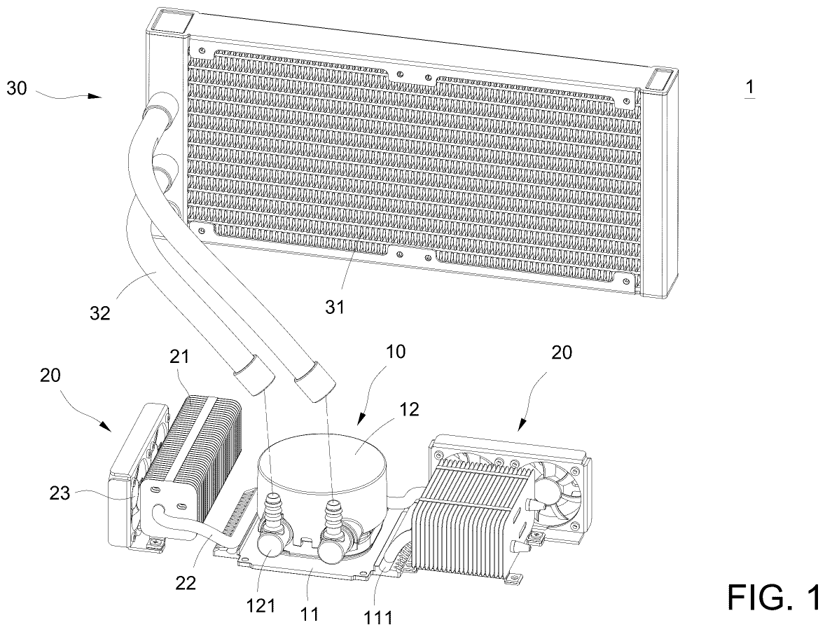

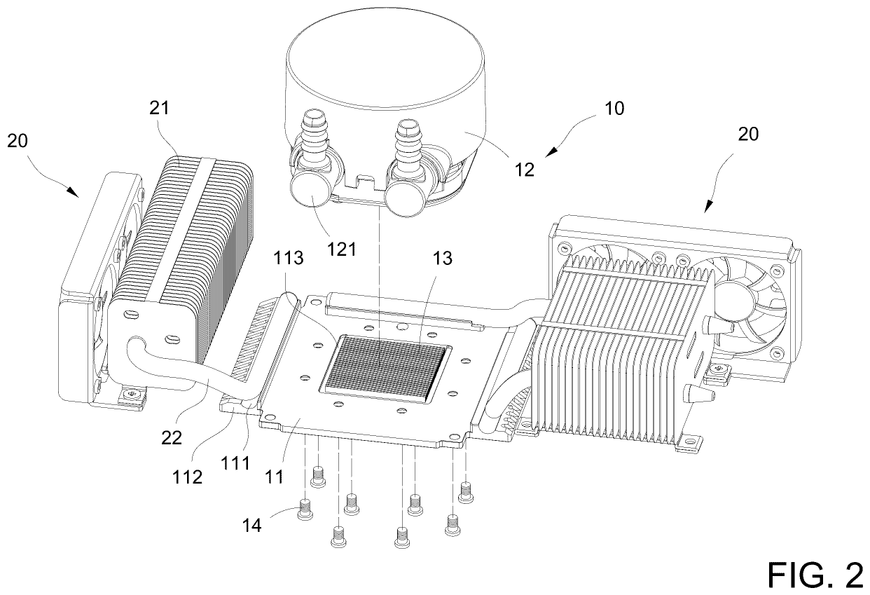

With reference to FIGS. 1 and 2 for the perspective assembled views of a liquid cooling device and a water cooling head assembly of the present disclosure respectively, the present disclosure discloses a liquid cooling device 1, which includes a water cooling head assembly 10, a heat dissipation module 20 and a water cooling radiator assembly 30. The heat dissipation module 20 is combined with a side of the water cooling head assembly 10. The water cooling radiator assembly 30 is connected to the water cooling head assembly 10, and forms a circulation loop with the water cooling head assembly 10.

The water cooling head assembly 10 includes a water cooling plate 11, a water cooling shell 12 combined with the water cooling plate 11, and a plurality of water cooling fins 13 arranged with a space apart from each other on the water cooling plate 11. In this embodiment, the water cooling plate 11 is provided with at least one embedding groove 111 located at a corresponding position on an outer periphery of the water cooling shell 12 and on a side facing the water cooling shell 12. The water cooling shell 12 is provided with a plurality of pipe joints 121. In addition, a protruding platform 112 is formed at the periphery of the water cooling plate 11 and a recess 113 is formed at the center position of the water cooling plate 11. The embedding groove 111 is located on the protruding platform 112. The water cooling fins 13 are disposed in the recess 113.

It is noteworthy that the water cooling plate 11 and the water cooling shell 12 are made of copper alloy or a metal with high thermal conductivity. Furthermore, the water cooling plate 11 and the water cooling shell 12 after being stacked are combined together and secured by a plurality of screws 14.

The heat dissipation module 20 is located on a side of the water cooling head assembly 10. The heat dissipation module 20 includes a plurality of heat dissipation fins 21 and at least one heat pipe 22. The heat dissipation fins 21 are arranged with a space apart from each other. One end of the heat pipe 22 is passed with the heat dissipation fins 21, and another end of the heat pipe 22 is combined in the embedding groove 111 of the water cooling plate 11. The heat pipe 22 absorbs heat from the water cooling plate 11 and conducts the heat to the heat dissipation module 20 to quickly remove and dissipate the heat, so as to improve heat dissipation efficiency.

It is noteworthy that the liquid cooling device 1 of the present disclosure includes a plurality of heat dissipation modules 20 installed on opposite sides of the water cooling head assembly 10 and used to quickly remove the heat from the water cooling plate 11. In actual use, the quantity of heat dissipation modules 20 is adjustable as needed.

Furthermore, the water cooling radiator assembly 30 is located on a side of the heat dissipation module 20 and communicated with the water cooling head assembly 10. The water cooling radiator assembly 30 includes a water cooling radiator 31 and a plurality of connecting pipes 32. One end of the connecting pipes 32 is connected to the water cooling radiator 31, and another end of the connecting pipes 32 is connected to the pipe joint 121 of the water cooling shell 12. In this way, the water cooling radiator assembly 30 is communicated with the water cooling head assembly 10 to form a closed circulation pipeline.

It is noteworthy that during the use of the liquid cooling device 1 of the present disclosure, the heat generating component is attached to the water cooling plate 11 of the water cooling head assembly 10. The heat of the heat generating component is conducted to the water cooling plate 11, and a circulation loop is formed by the water cooling head assembly 10 and the water cooling radiator assembly 30 and used to exchange heat and remove the heat from the coolant. Furthermore, a part of heat from the water cooling plate 11 is conducted to the heat pipe 22, and transmitted to the heat dissipation module 20 through the heat pipe 22, so as to cool the water cooling plate 11, and achieve the effect of continuously dissipating heat from the heat generating component.

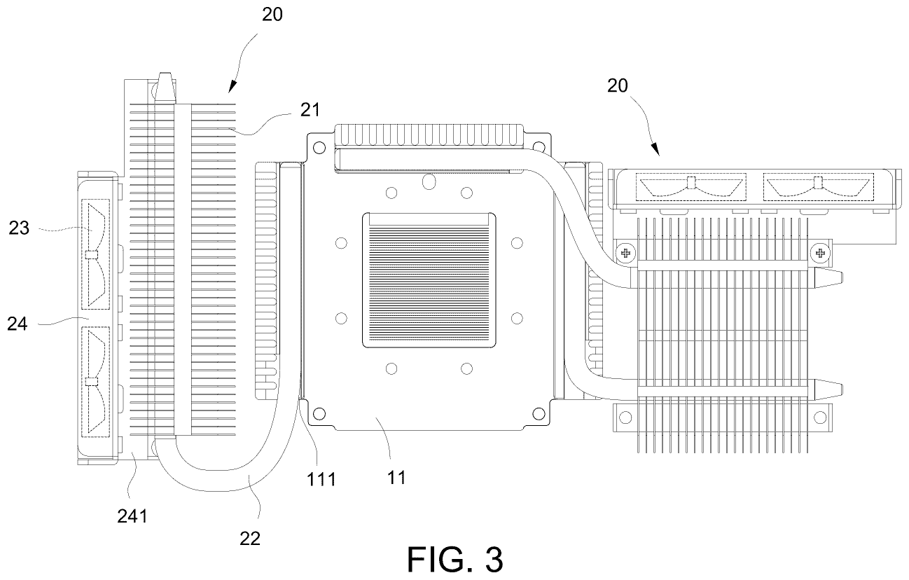

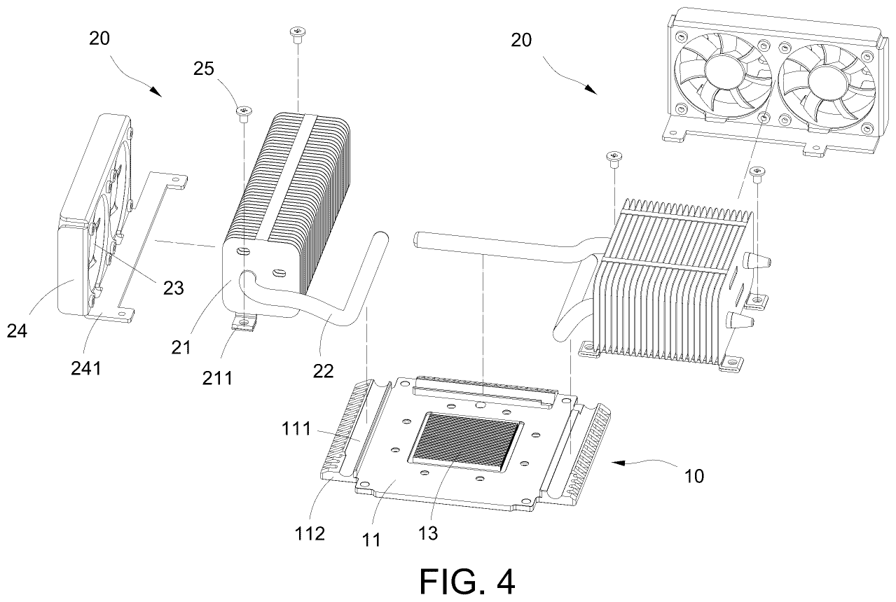

With reference to FIGS. 3 and 4 for the plan configuration view and the perspective assembled view of the heat dissipation module in accordance with an embodiment of the present disclosure respectively, the heat dissipation module 20 of this embodiment further includes a cooling fan 23 combined with a side of the heat dissipation fins 21. In an exemplary embodiment, the heat dissipation module 20 further includes a fan frame 24 of the cooling fan 23. The fan frame 24 is provided with a plurality of protruding plates 241 facing the water cooling head assembly 10. In addition, the heat dissipation fins 21 are provided with a plurality of locking plates 211. The fan frame 24 is passed and secured to the protruding plates 241 and the locking plates 211 by a plurality of fasteners 25, so as to combine the cooling fan 23 with a side of the heat dissipation fins 21. The cooling fan 23 generates a forced airflow to remove the heat from the heat dissipation fins 21.

It is noteworthy that the liquid cooling device 1 of the present disclosure is provided with a plurality of heat dissipation modules 20, and the heat dissipation fin 21 of each heat dissipation module 20 is passed with a different quantity of heat pipes 22. In this embodiment, there are multiple embedding grooves 111 of the water cooling plate 11 and multiple heat pipes 22 of the heat dissipation module 20. In addition, the embedding grooves 111 are respectively located on different sides of the periphery of the water cooling plate 11.

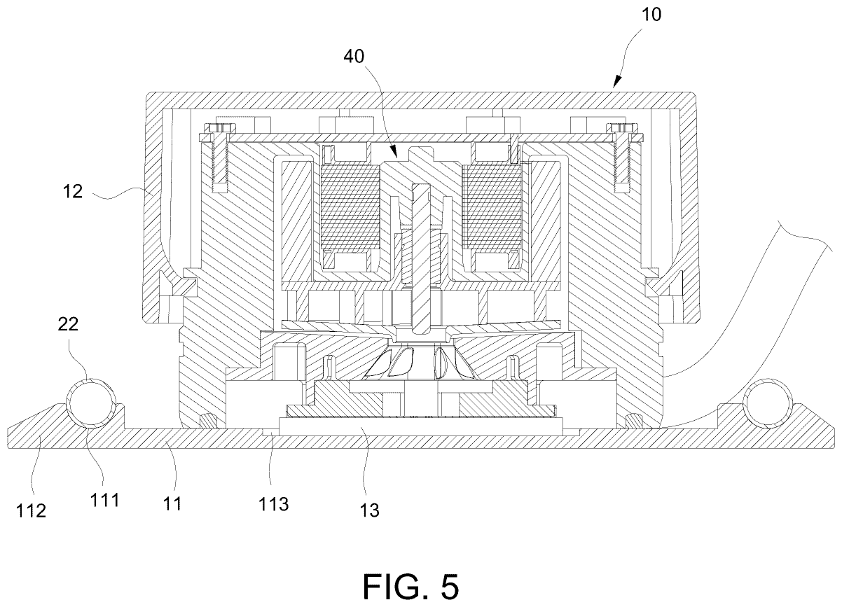

With reference to FIG. 5 for the cross-sectional view of a water cooling head assembly of the present disclosure, the water cooling head assembly 10 includes a water cooling plate 11, and a water cooling shell 12 and a plurality of water cooling fins 13 which are combined with the water cooling plate 11. The water cooling fins 13 are arranged with a space apart from each other in the recess 113 of the water cooling plate 11. In addition, the periphery of the water cooling plate 11 is formed with a protruding platform 112. The protruding platform 112 is provided with an embedding groove 111, and heat pipe is embedded in the embedding groove 111. Furthermore, the liquid cooling device 1 of the present disclosure further includes a water pump 40 installed in the water cooling shell 12 for increasing the water pressure and water flow velocity in the water cooling head assembly 10 to improve the heat dissipation efficiency of the liquid cooling device 1.

The above examples merely represent preferred embodiments of the present disclosure and they are not intended to limit the scope of the present disclosure. Therefore, any equivalent techniques, means, or variations made by utilizing the content of the specification and drawings of the present disclosure are likewise included within the scope of the present disclosure.

What is claimed is:

1. A liquid cooling device, for dissipating heat from a heat source, comprising:
a water cooling head assembly, comprising a water cooling plate attached to the heat source and combined with a water cooling shell of the water cooling plate, the water cooling plate comprising at least one embedding groove located at a corresponding position on an outer periphery of the water cooling shell and on a side facing the water cooling shell, and the water cooling shell being provided with a plurality of pipe joints;
a heat dissipation module, comprising a plurality of heat dissipation fins and at least one heat pipe, wherein one end of the heat pipe is passed with the heat dissipation fins, and another end of the heat pipe is combined in the embedding groove; and
a water cooling radiator assembly, comprising a water cooling radiator and a plurality of connecting pipes, wherein one end of the connecting pipe is coupled to the water cooling radiator, and another end of the connecting pipe is coupled to the pipe joint.

2. The liquid cooling device according to claim 1, wherein the water cooling head assembly comprises a plurality of water cooling fins arranged with a space apart from each other on the water cooling plate, and the water cooling fins protrude into the water cooling shell.

3. The liquid cooling device according to claim 2, wherein the water cooling plate is formed with a recess at the center position thereof, and the water cooling fins are located in the recess.

4. The liquid cooling device according to claim 1, wherein the periphery of the water cooling plate is formed with a protruding platform, and the embedding groove is located on the protruding platform.

5. The liquid cooling device according to claim 1, wherein the water cooling plate and the water cooling shell after being stacked are secured by a plurality of screws and combined together.

6. The liquid cooling device according to claim 1, wherein the quantity of the at least one embedding groove and the quantity of the at least one heat pipe are plural, and the embedding grooves are respectively located on different sides of the periphery of the water cooling plate.

7. The liquid cooling device according to claim 1, wherein the heat dissipation module further comprises a cooling fan combined with a side of the heat dissipation fins.

8. The liquid cooling device according to claim 7, wherein the heat dissipation module further comprises a fan frame combined with the cooling fan, the fan frame comprises a plurality of protruding plates facing the water cooling head assembly, the heat dissipation fins are provided with a plurality of locking plates, and the fan frame is passed and secured to the protruding plates and the locking plates by a plurality of fasteners to combine the cooling fan with a side of the heat dissipation fins.

9. The liquid cooling device according to claim 1, wherein the quantity of heat dissipation modules is plural, and the heat dissipation modules are respectively located on opposite sides of the water cooling head assembly.

10. The liquid cooling device according to claim 1, further comprising a water pump installed in the water cooling shell.
